(19) United States
(12) Patent Application Publication
(10) Pub. No.: US 2005/0263891 A1
(43) Pub. Date: Dec. 1, 2005

(54) Diffusion barrier for damascene structures

(76) Inventors: Bih-Huey Lee, Hsinchu County (TW); Hong-Yuan Chu, Taichung City (TW); Ping-Kun Wu, Hsin-Chu City (TW); Ching-Wen Lu, Hsinchu County (TW); Jing-Cheng Lin, HsinChu County (TW); Shau-Lin Shue, Hsinchu (TW); Shing-Chyang Pan, Hsinchu County (TW)

Correspondence Address: SLATER & MATSIL, L.L.P., 17950 PRESTON ROAD, SUITE 1000, DALLAS, TX, 75252, US

(21) Appl. No.: 11/100,912

(22) Filed: Apr. 7, 2005

Related U.S. Application Data
(60) Provisional application No. 60/575,761, filed on May 28, 2004.

(51) Int. Cl. H01L 21/4763

(52) U.S. Cl. 257/751

(57) ABSTRACT

A damascene structure for semiconductor devices is provided. In an embodiment, the damascene structure includes trenches formed over vias that electrically couple the trenches to an underlying conductive layer such that the trenches have varying widths. The vias are lined with a first barrier layer. The first barrier layers along the bottom of vias are removed such that a recess formed in the underlying conductive layer. The recesses formed along the bottom of vias are such that the recess below narrower trenches is greater than the recess formed below wider trenches. In another embodiment, a second barrier layer may then be formed over the first barrier layer. In this embodiment, a portion of the conductive layer may be interposed between the first barrier layer and the second barrier layer.

This application claims the benefit of U.S. Provisional Application No. 60/575,761 filed on May 28, 2004, entitled Diffusion Barrier for Damascene Structures, which application is hereby incorporated herein by reference.

### TECHNICAL FIELD

The present invention relates generally to semiconductors and, more particularly, to a semiconductor structure having a damascene structure.

### BACKGROUND

Complementary metal-oxide-semiconductor (CMOS) technology is the dominant semiconductor technology used for the manufacture of ultra-large scale integrated (ULSI) circuits today. Size reduction of the semiconductor structures has provided significant improvement in the speed, performance, circuit density, and cost per unit function of semiconductor chips over the past few decades. Significant challenges, however, are faced as the sizes of CMOS devices continue to decrease.

One such challenge is the fabrication of interconnect structures. CMOS devices typically include semiconductor structures, such as transistors, capacitors, resistors, and the like, formed on a substrate. One or more conductive layers formed of a metal or metal alloy separated by layers of a dielectric material are formed over the semiconductor structures to interconnect the semiconductor structures and to provide external contacts to the semiconductor structures. Trenches and vias are formed in the dielectric layers to provide an electrical connection between metal layers and/or a metal layer and a semiconductor structure.

Generally, one or more adhesion/barrier layers are formed in the trench and via to prevent electron diffusion from the conductive material, e.g., copper, aluminum, or the like, into the surrounding dielectric material and to enhance the adhesive properties of the conductive material to the dielectric material. For example, it is common to utilize a first barrier layer formed of tantalum, which provides good adhesive qualities to the dielectric layer. A second barrier layer is commonly formed of tantalum nitride, which provides good adhesion qualities to the first tantalum barrier layer and a filler material, such as copper, that may be used to fill the trench and the via.

When decreasing the size of vias, particularly with vias less than about 0.15 μm, however, it has been found that the thickness of the barrier layer deposited along the bottom of the via may be dependent upon the width of the trench. This difference in the thickness of the barrier layers along the bottom of the via may affect the electrical characteristics of the of via, such as the contact resistance.

For example, FIG. 1a illustrates a substrate 100 having a conductive layer 110, an etch buffer layer 112, and an inter-metal dielectric (IMD) layer 114 formed thereon. A wide trench 120 and via 122 are formed on the left side, and a narrow trench 124 and via 126 are formed on the right side. One or more barrier layers, such as barrier layers 130, are formed over the surface, and the vias 122, 126 and trenches 120, 124 are filled with a conductive plug.

As illustrated in FIG. 1a, the thickness W₁ of the barrier layers 130 along the bottom of the via 122 associated with the wider trench 120 is greater than the thickness W₂ of the barrier layers 130 along the bottom of the via 126 associated with the narrow trench 124. Due to the different thickness of the barrier layers 130, the electrical characteristics of the via 122 may be different than the electrical characteristics, e.g., contact resistance, of the via 126.

Another problem may occur during the damascene process when the underlying conductive layer is exposed, cleaned, or etched. In particular, a certain amount of the copper conductor layer under the via opening may be sputtered or partially removed and redeposited along the sidewalls of the via. While the recess created in the copper conductive layer advantageously reduces the resistance, the redeposited layer of copper may also adversely affect the adhesion of a subsequent seed layer with the barrier layers and may also decrease the reliability of the IC. Furthermore, the redeposited copper layer along the sidewalls of the via may induce electron migration and copper diffusion into the dielectric layer, thereby causing the structure to fail.

For example, FIGS. 1b-1d illustrate a substrate 101 at various stages of processing performed to form a conventional barrier layer structure within a via. In FIG. 1b, the substrate 101 having a conductive layer 140, an etch buffer layer 142, and an inter-metal dielectric (IMD) layer 144 formed thereon is shown. A via 146 is formed in the IMD layer 144 and the etch buffer layer 142 by, for example, standard damascene or dual-damascene processes.

In FIG. 1c, a cleaning process is performed to remove any native oxide, copper oxide, or polymer from the surface of the conductive layer 140 within the via 146. As discussed above, a portion of the conductive layer 140 may be redeposited along the sidewalls of the via 146 as indicated by areas 128. A barrier layer 150 is then formed over the surface, and the via 146 is filled with copper 132 as illustrated in FIG. 1d. As discussed above, the redeposited copper in areas 128 may adversely affect the performance and reliability of the IC.

Therefore, there is a need for a damascene structure that prevents or reduces variations of contact resistance between a plug in a via and an underlying conductive layer and/or that prevents or reduces the effects of a redeposited conductive layer that may occur during processing.

### SUMMARY OF THE INVENTION

These and other problems are generally solved or circumvented, and technical advantages are generally achieved, by preferred embodiments of the present invention which provides semiconductor structure with a barrier layer in a damascene opening.

In accordance with an embodiment of the present invention, a semiconductor structure having a barrier layer formed in a damascene opening is provided. The semiconductor structure comprises a conductive layer and a dielectric layer. A first trench and a first via is formed through the dielectric layer, and a second trench and a second via is formed through the dielectric layer, wherein the second trench is narrower than the first trench. A first barrier layer is formed along the sidewalls of the first trench, the first via, the second trench, and the second via. The first barrier layer along the bottom of the first via and the second via is substantially removed. A first recess formed in the conductive layer along the bottom of the first via is less than a second recess formed in the conductive layer along the bottom of the second via. A second barrier layer may be formed along surfaces of the first trench, the first via, the second trench, and the second via. Conductive plugs formed over the second barrier layer in the first trench, the first via, the second trench, and the second via.

In accordance with another embodiment, a semiconductor structure is provided. The semiconductor structure comprises a substrate having a dielectric layer overlying a conductive layer. A via is formed through the dielectric layer to the underlying conductive layer. The conductive layer is preferably recessed. A first barrier layer is formed along the sidewalls of the via with a portion of the first barrier layer having redeposited material from the conductive layer thereon. A second barrier layer is formed over the first barrier layer and the redeposited material, thereby encapsulating the redeposited material between the first barrier layer and the second barrier layer. The via is filled with a conductive material.

In accordance with still another embodiment, a semiconductor structure is provided. The semiconductor structure comprises a substrate having a conductive layer formed thereon; a dielectric layer overlying the conductive layer; and a via filled with a conductive material formed through the dielectric layer and in electric contact with at least a portion of the conductive layer, the via having a bottom portion and sidewalls; wherein the via comprises at least one barrier layer along the bottom portion and a plurality of barrier layers along the sidewalls, and wherein the bottom portion has fewer barrier layers formed thereon than the sidewalls.

In accordance with yet another embodiment, a semiconductor structure is provided. The semiconductor structure comprises a substrate having a conductive layer formed thereon; an etch buffer layer over the conductive layer; a dielectric layer overlying the etch buffer layer; and an opening through the dielectric layer and the etch stop layer, the opening being filled with a conductive material in electric contact with at least a portion of the conductive layer, the opening having a first dimension at the surface of the dielectric layer and a second dimension at the etch stop layer; wherein the conductive layer has a recess under the opening, the recess being greater than about 50 Å when the ratio of the first dimension to the second dimension is less than about 10 and being less than about 50 Å when the ratio of the first dimension to the second dimension is greater than about 10.

In accordance with another embodiment, a semiconductor structure is provided. The semiconductor structure comprises a substrate having a conductive layer formed thereon; an etch buffer layer over the conductive layer; a dielectric layer overlying the etch buffer layer; an opening through the dielectric layer and the etch buffer layer, the opening being filled with a conductive material in electric contact with at least a portion of the conductive layer; and a recess in the conductive layer under the opening, the recess having a first dimension at the etch stop layer and a second dimension at a bottom of the recess, the second dimension being less than about 95% of the first dimension.

It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1a-1d illustrate conventional barrier layers in a damascene structure;

FIGS. 2a-2f illustrate steps that may be performed to fabricate barrier layers in accordance with an embodiment of the present invention; and

FIGS. 3a-3f illustrate steps that may be performed to fabricate barrier layers in accordance with an embodiment of the present invention.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed herein are merely illustrative of specific ways to make and use the invention, and do not limit the scope of the invention.

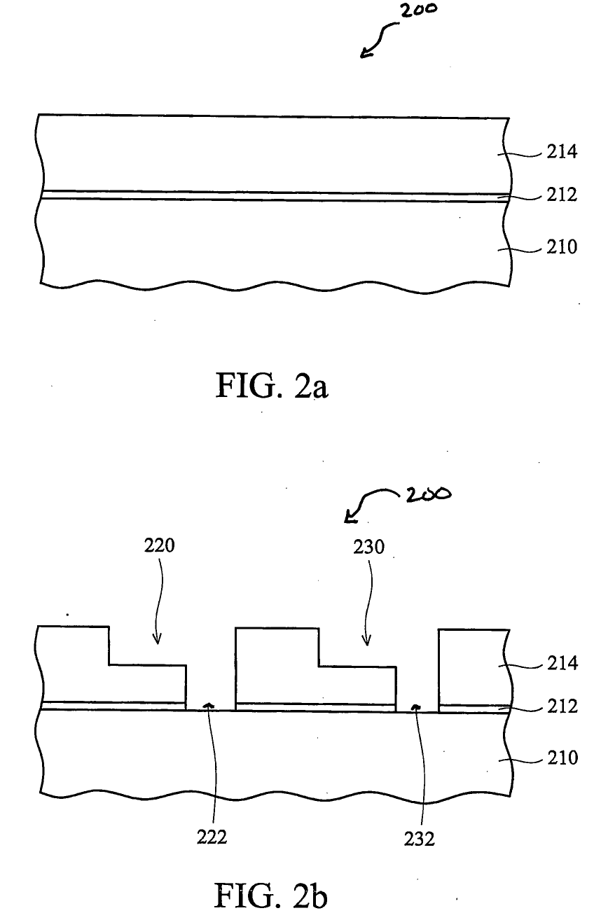

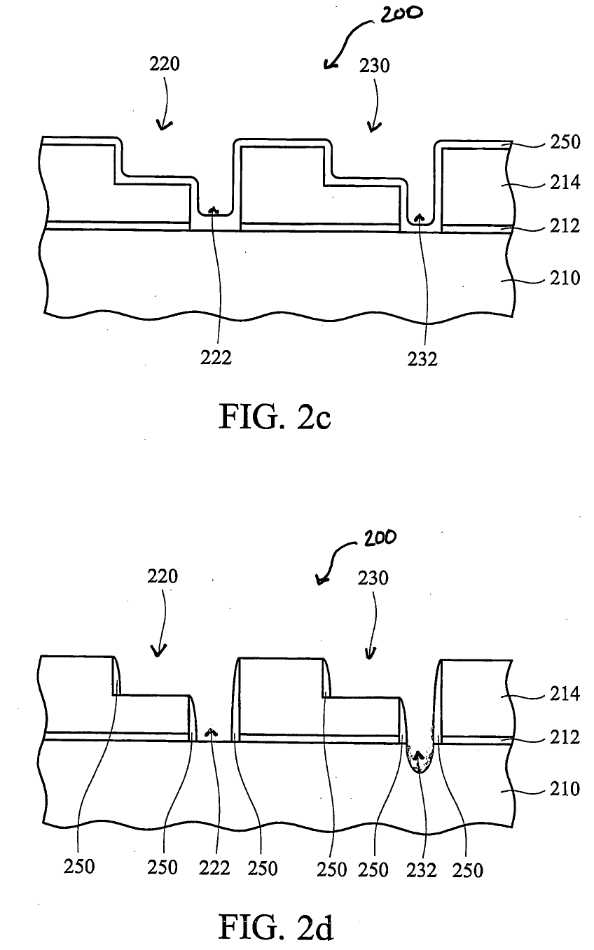

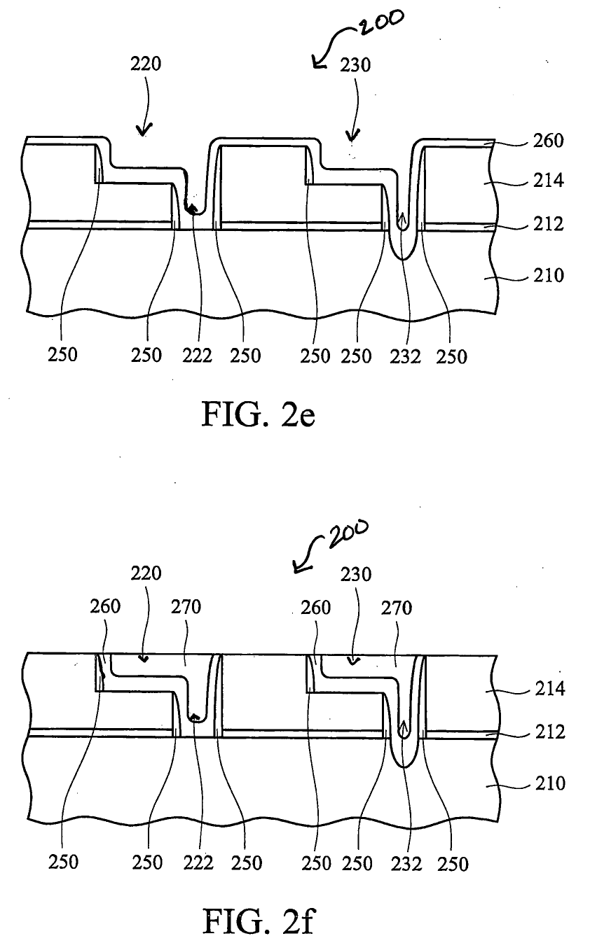

Referring now to FIG. 2a, a substrate 200 is provided having a conductive layer 210, an etch buffer layer 212, and an IMD layer 214. Although it is not shown, the substrate 200 may include circuitry and other structures. For example, the substrate 200 may have formed thereon transistors, capacitors, resistors, and the like. In an embodiment, the conductive layer 210 is a metal layer that is in contact with electrical devices or another metal layer.

The conductive layer 210 may be formed of any conductive material, but an embodiment of the present invention has been found to be particularly useful in applications in which the conductive layer 210 is formed of copper. As discussed above, copper provides good conductivity with low resistance. The etch buffer layer 212 provides an etch buffer that may be used to selectively etch the IMD layer 214 in a later processing step. In an embodiment, the etch buffer layer 212 may be formed of a dielectric material such as a silicon-containing material, nitrogen-containing material, or the like. The IMD layer 214 is preferably formed of a low-K (less than about 3.0) dielectric material, such as fluorine doped dielectric, carbon doped dielectric, or the like. In a preferred embodiment, the thickness of the etch buffer layer 212 is greater than about 10% of the thickness of the underlying conductive layer 210.

It should be noted that the materials selected to form the conductive layer 210, the etch buffer layer 212, and the IMD layer 214 should be selected such that a high etch selectivity exists between the IMD layer 214 and the etch buffer layer 212 and between etch buffer layer 212 and the conductive layer 210. In this manner, damascene structures may be formed in the layers as described below. Accordingly, in an embodiment, the IMD layer 214 comprises silicon oxide (or FSG) formed by deposition techniques such as CVD. In this embodiment, silicon nitride (SiNₓ, 3>x>0) or silicon carbon nitride (SiCₓN_{y}, 5≧(x, y)>0) has been found to be a suitable material for the etch stop layer 212 in which a copper damascene structure is being fabricated.

Referring now to FIG. 2b, trenches 220, 230 and vias 222, 232 are formed in the IMD layer 214. The trenches 220, 230 and vias 222, 232 may be formed by a dual-damascene process utilizing photolithography techniques known in the art. Generally, photolithography involves depositing a photoresist material and then irradiating (exposing) and developing the photoresist material in accordance with a specified pattern to remove a portion of the photoresist material. The remaining photoresist material protects the underlying material from subsequent processing steps, such as etching. The etching process may be a wet or dry, anisotropic or isotropic, etch process, but preferably is an anisotropic dry etch process. After the etching process, the remaining photoresist material may be removed.

In the embodiment illustrated in FIG. 2c, the trench 220 is wider than the trench 230, even though the vias 222, 232 may have substantially the same dimensions. For example, in an embodiment the wider trench 220 may have a width of about 0.5 μm to about 10 μm, and the narrower trench 230 may have a width of less than about 0.5 μm. More preferably, a ratio of the wider trench 220 to the narrower trench 230 is greater than about 3. The vias 222, 232 may both have a width of about 0.04 μm to about 0.15 μm, and more preferably, less than about 0.15 μm. Other dimensions may be used.

In an embodiment in which the IMD layer 214 is formed of FSG, the etch buffer layer 212 is formed of silicon nitride, and the conductive layer 210 is formed of copper, the trenches 220, 230 and vias 222, 232 may be etched utilizing a solution of CF₄, C₅F₈, or the like, wherein the etch buffer layer 212 acts as an etch buffer. Thereafter, another etching process utilizing, for example, a solution of CF₄ may be performed to remove the etch buffer layer 212 within the vias 222, 232, thereby exposing the surface of the conductive layer 210.

It should be noted that a pre-clean process may be performed to remove impurities along the sidewalls of the via and to clean the underlying conductive layer. The pre-clean process may be a reactive or a non-reactive pre-clean process. For example, a reactive process may include a plasma process using a hydrogen-containing plasma, and a non-reactive process may include a plasma process using an argon-containing plasma.

FIG. 2c illustrates the substrate 200 of FIG. 2b after a first barrier layer 250 has been formed. The first barrier layer 250 may comprise a dielectric or conductive barrier layer, such as a nitrogen-containing layer, a carbon-containing layer, a hydrogen-containing layer, a silicon-containing layer, a metal or metal-containing layer doped with an impurity (e.g., boron), such as tantalum, tantalum nitride, titanium, titanium nitride, titanium zirconium, titanium zirconium nitride, tungsten, tungsten nitride, cobalt boron, an alloy, combinations thereof, or the like. The first barrier layer 250 may be formed, for example, by physical vapor deposition (PVD), atomic layer deposition (ALD), spin-on deposition, or other suitable methods. The first barrier layer 250 may have a thickness between about 5 Å and about 300 Å.

Referring now to FIG. 2d, a process is performed to remove the first barrier layer 250 along the bottom of the vias 222, 232 and to clean the surface of the conductive layer 210. As illustrated in FIG. 2c and discussed above, the first barrier layer 250 formed in the via 222 may be thicker than the first barrier layer 250 formed in the via 232. To reduce the effect of the thicker first barrier layer 250, which may be a dielectric barrier layer, the first barrier layer 250 may be removed along the bottom of the vias 222, 232 by, for example, an ion sputtering process or plasma-containing process. The plasma-containing process may be performed in an argon-containing, hydrogen-containing, helium-containing, nitrogen-containing, metal-containing, or a combination thereof plasma environment. The ion sputter process may be performed in a metal or non-metal ion-containing environment. A sputter etch/deposition process may also be used such that the first barrier layer 250 is substantially removed along the bottom of the via while leaving at least a portion of the first barrier layer 250 along the bottom of the trench.

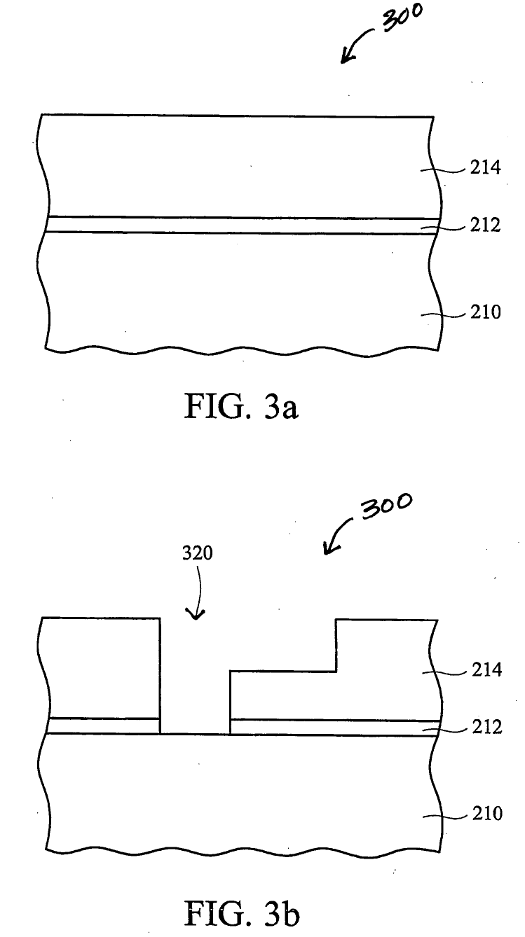

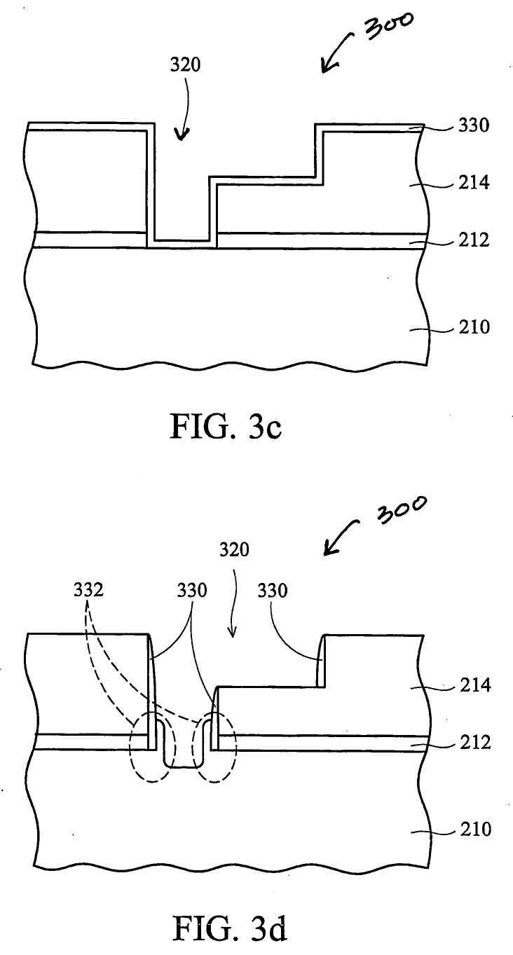

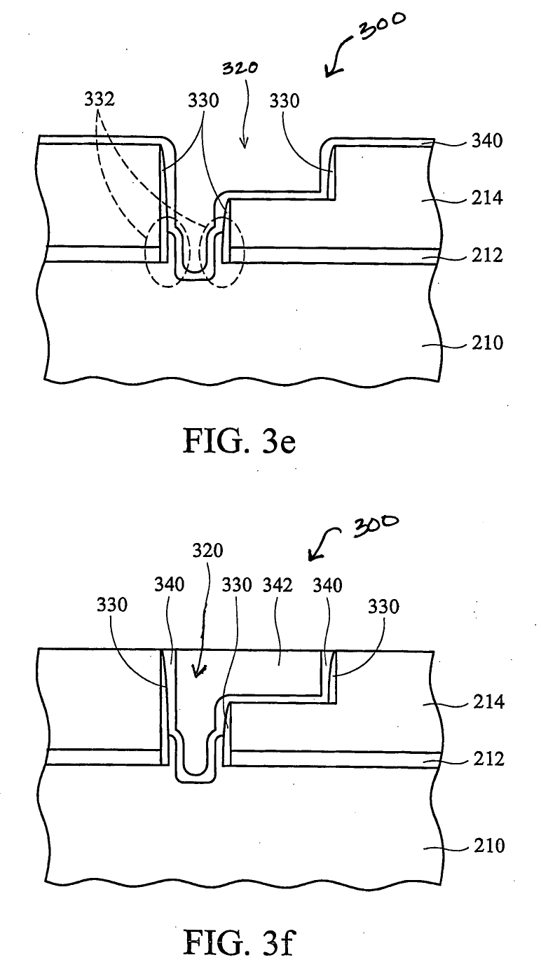

The ion sputter or plasma process used to remove the first barrier layer 250 along the bottom of the vias 222, 232 may result in a re-deposited conductive material (not shown) along the sidewalls of the vias 222, 232 on the first barrier layer 250, creating recesses in the conductive layer 210 along the bottoms of one or both of the via 222, 232. It should be noted, however, that the first barrier layer 250 is positioned between the redeposited conductive material of the conductive layer 210 and the IMD layer 214. In this manner, the first barrier layer 250 helps prevent or reduce electron migration and diffusion into the IMD layer 214. This process is described in greater detail below with reference to FIGS. 3a-3f.

Because the first barrier layer 250 is thinner in via 232 than the first barrier layer 250 in via 222, the etching process results in removing a portion of the conductive layer 210 under via 232. It has been found that the etching process may etch the conductive layer 210 at a much faster rate than the first barrier rate, sometimes having an etch ratio of the conductive layer 210 to the first barrier layer 250 of 5.5 to 1. It is preferred, however, to adjust the etch parameters such that substantially all of the first barrier layer 250 is removed along the bottom of vias 222, 232. As a result, the amount of recess may vary dependent upon the trench and via dimensions. In this manner, it has been found that the contact resistance may be better controlled.

It should be noted that the first barrier layer 250 may also be removed from other surfaces substantially perpendicular to the ion sputter direction. For example, in the embodiment illustrated in FIG. 2d, the first barrier layer 250 is removed from the top surface of the IMD layer 214 and the horizontal surface of the dual-damascene structure within the IMD layer 214.

In a preferred embodiment, the depth of the recess (as measured from the surface of the conductive layer 210) is greater than about 50 Å if the ratio of the width of the trench to the width of the via is less than about 10, and is less than about 50 Å if the ratio of the width of the trench to the width of the via is greater than about 10. It is also preferred that the recess formed in the conductive layer 210 have rounded comers and that the width of the recess along the bottom of the recess is less than about 95% of the width of the opening formed in the etch stop layer 212.

Referring now to FIG. 2e, a second barrier layer 260 is formed. The second barrier layer 260 preferably comprises a conductive material, such as a silicon-containing layer, carbon-containing layer, nitrogen-containing layer, hydrogen-containing layer, or a metal or a metal compound containing layer doped with an impurity (e.g., boron), such as tantalum, tantalum nitride, titanium, titanium nitride, titanium zirconium, titanium zirconium nitride, tungsten, tungsten nitride, cobalt, nickel, ruthenium, palladium, alloys, or combinations thereof, but more preferably, relatively pure titanium, tantalum, cobalt, nickel, palladium, or the like. The second barrier layer 260 may be formed by a process such as physical vapor deposition (PVD), chemical vapor deposition (CVD), plasma-enhanced CVD (PECVD), low-pressure CVD (LPCVD), atomic layer deposition (ALD), spin-on deposition, or other suitable methods. The second barrier layer 260 may comprise multiple layers.

FIG. 2f illustrates the substrate 200 after trenches 220, 230 and vias 222, 232 are filled with conductive plugs 270 and the surface planarized. In an embodiment, the conductive plug 270 comprises a copper material formed by depositing a copper seed layer and forming a copper layer via an electro-plating process. The step may be planarized by, for example, a chemical-mechanical polishing (CMP) process.

It should be noted that in the preferred embodiment, one or more barrier layers are placed along the bottom of the via between the conductive plugs 270 and the underlying conductive layer 210. One reason for this is misalignment of the vias. It has been found that at times the via may not be directly placed above the conductive layer 210. In these cases, a portion of the via may be positioned over a dielectric material. To prevent or reduce electron diffusion from the conductive plugs 270 into the underlying dielectric material, it is preferred that one or more barrier layers, such as the second barrier layer 260, be located along the bottom of the vias 222, 232. It is also preferred that barrier layers formed along the bottom of the vias be formed of a conductive material.

Thereafter, standard processes may be used to complete fabrication and packaging of the semiconductor device.

It should be noted that in embodiments in which the underlying conductive layer is exposed or recessed, that portions of the underlying conductive layer may be redeposited along the sidewalls of the via. Because this redeposited layer along the sidewalls may induce electron migration and copper diffusion into the dielectric layer, as well as possibly causing adhesion problems, it has been found to be beneficial to deposit a first barrier layer, remove the first barrier layer along the bottom of the via, creating a recess in the underlying conductive layer, and then depositing a second barrier layer. This process is described in greater detail with reference to FIGS. 3a-3f.

Referring first to FIG. 3a, a substrate 300 is provided having a conductive layer 210, an etch stop layer 212, and an IMD layer 214, wherein like reference numerals refer to like elements in FIGS. 2a-2f. Although it is not shown, the substrate 300 may include circuitry and other structures. For example, the substrate 300 may have formed thereon transistors, capacitors, resistors, and the like.

Referring now to FIG. 3b, a via 320 is formed. It should be noted that the via 320 is illustrated as a dual-damascene structure for illustrative purposes only and may be formed by one or more process steps (e.g., a single damascene process). The via 320 may be patterned and etched as described above with reference to FIG. 2b.

It should be noted that this embodiment is being illustrated with reference to a single trench and via. Embodiments of the present invention may be equally applicable to multiple trenches and vias, such as the embodiment illustrated in FIGS. 2a-2f.

FIG. 3c illustrates the substrate 300 of FIG. 3b after a first barrier layer 330 has been formed. The first barrier layer 330 may be formed of the same materials and in the same manner as the first barrier layer 250 of FIG. 2c.

It should be noted that in an alternative embodiment, the first barrier layer 330 may be deposited prior to removing the etch buffer layer 212. In this embodiment, the first barrier layer 330 is deposited after the via 320 has been formed, but before removing the etch buffer layer 212 along the bottom of the via 320. After depositing the first barrier layer 330, the first barrier layer 330 and the etch buffer layer 312 along the bottom of the via are both removed.

Referring now to FIG. 3d, a process is performed to remove the first barrier layer 330 along the bottom of the via 320, thereby exposing the underlying conductive layer and creating a recess in the conductive layer 210. The first barrier layer 330 may be removed along the bottom of the via 320 by, for example, an ion-sputtering process or plasma-containing process. The plasma-containing process may be performed in an argon-containing, hydrogen-containing, helium-containing, nitrogen-containing, metal-containing, or a combination thereof plasma environment. The ion sputter process may be performed in a metal or non-metal ion-containing environment. In a preferred embodiment, argon or tantalum ions are used in the etching process. A sputter etch/deposition process may also be used such that the first barrier layer 330 is substantially removed along the bottom of the via 320 while leaving at least a portion of the first barrier layer 330 along the bottom of the trench.

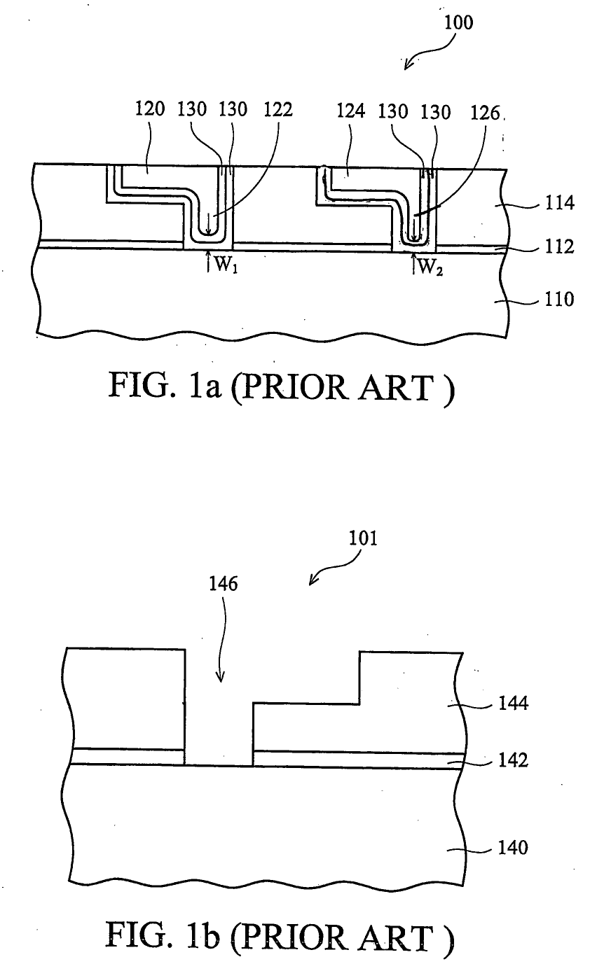

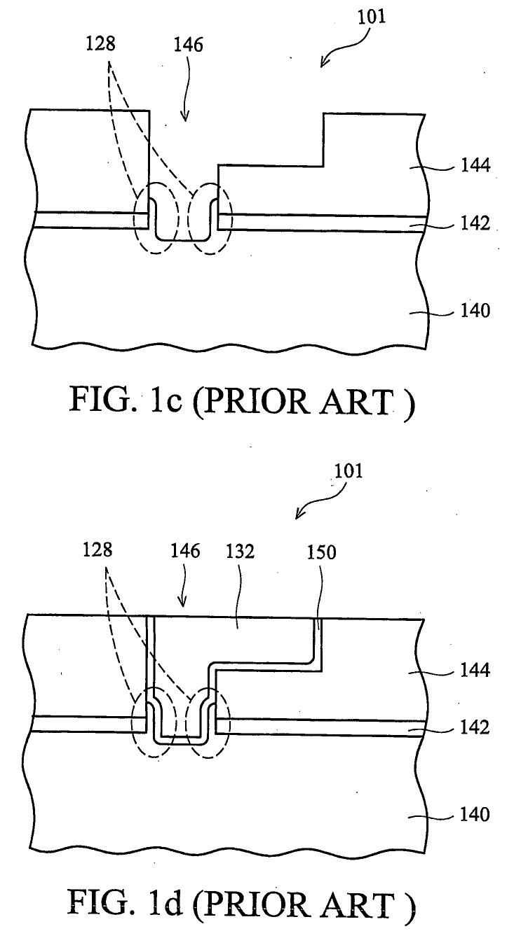

As indicated by the areas 332 in FIG. 3d, the ion sputter or plasma process may result in a redeposited conductive material along the sidewalls of the via 320 on the first barrier layer 330. It should be noted, however, that the first barrier layer 330 is positioned between the redeposited conductive material of the conductive layer 210 and the IMD layer 214. The recess process in the conductive layer controls the redeposited conductive material of the conductive layer 210 such that a uniform contact resistance may be maintained. Also, the redeposited conductive material would gain the contact area of via to the conductive layer 210, therefore a lower contact resistance is achieved. The first barrier layer 330 prevents or reduces the interdiffusion between the conductive layer 210 and the dielectric layer, which is not taught in prior art as discussed above with reference to FIG. 1. In this manner, the first barrier layer 330 helps prevent or reduce electron migration and diffusion into the IMD layer 214.

It should also be noted that the surface of the conductive layer 210 may be recessed in the via 320 opening as a result of the ion sputter or plasma process. In an embodiment, the depth of the recess portion may be about 1 to about 100 nanometers. The redeposited layer may also contain a hydrogen-containing, oxygen-containing, carbon-containing, or fluorine-containing material.

It should be noted that the first barrier layer 330 may also be removed from other surfaces because of the directional aspect of the etching processes used to remove the first barrier layer 330 along the bottom of the via 320. For example, in an embodiment in which the etching process is tuned such that the direction of etching, e.g., the ion sputtering direction, is substantially perpendicular to the surfaces of the bottom of the via 320, the first barrier layer 330 may also be removed from top surface of the IMD layer 214 and the horizontal surface of the dual-damascene structure within the IMD layer 214.

Referring now to FIG. 3e, a second barrier layer 340 is formed. The second barrier layer 340 preferably comprises a conductive material, such as a silicon-containing layer, carbon-containing layer, nitrogen-containing layer, hydrogen-containing layer, or a metal or a metal compound containing layer, such as tantalum, tantalum nitride, titanium, titanium nitride, titanium zirconium, titanium zirconium nitride, tungsten, tungsten nitride, cobalt, nickel, ruthenium, palladium, or alloys, or combinations thereof, but more preferably, relatively pure titanium, tantalum, cobalt, nickel, palladium, or the like. The second barrier layer 340 may be formed by a process such as physical vapor deposition (PVD), chemical vapor deposition (CVD), plasma-enhanced CVD (PECVD), low-pressure CVD (LPCVD), atomic layer deposition (ALD), spin-on deposition, or other suitable methods. The second barrier layer 340 may comprise multiple layers.

To achieve a better step coverage on the sidewall and to achieve good resistivity properties along the bottom of the via 320, the thickness of the second barrier layer 340 along the bottom of the via 320 may be less than the total thickness of the first barrier layer 330 and the second barrier layer 340 along the sidewall of the vias 320. (Note that the first barrier layer does not run along the bottom of the via.)

The barrier layers on the sidewall may also have different thicknesses to achieve step coverage. The preferred thickness ratio of the first barrier layer 330 to the second barrier layer 340 along the sidewall of the via 320 is about 1:10 to about 10:1. In an embodiment, the first barrier layer 330 has a thickness of about 5 to 300 Å, and the second barrier layer 340 has a thickness of about 5 to about 300 Å.

FIG. 3f illustrates the substrate 300 after the via 320 is filled with a conductive plug 342 and the surface planarized. In an embodiment, the conductive plug 342 comprises a copper material formed by an electrochemical deposition (ECD) process. Generally, ECD processes first deposit a seed layer by, for example, a PVD or CVD deposition process. Thereafter, the copper layer is formed via an electro-plating process wherein the substrate 300 is placed in a plating solution and a current is applied. The substrate 300 may be planarized by, for example, a chemical-mechanical polishing (CMP) process.

Thereafter, standard processes may be used to complete fabrication and packaging of the semiconductor device.

As will be appreciated by one skilled in the art, an embodiment of the present invention utilizes two or more barrier layers along the sidewall of a damascene opening. The re-depositing of an underlying conductive layer that may occur during processing, such as a cleaning or an etching step, is positioned between two sidewall barrier layers, helping to resolve or reduce the adhesion and reliability problems of the redeposited conductive layer. Furthermore, the continuity of the sidewall barrier may eliminate or reduce electron migration and copper diffusion.

Embodiments of the present invention also allow the recess in the underlying conductor to be controlled with less effect on reliability because the redeposited conductive layer was protected by the second barrier layer. The bottom barrier layer in the damascene opening has a thickness and fewer layers than sidewall barrier layers providing lower resistivity. (Generally, the fewer barrier layers on bottom, the better resistivity performance.) It should also be noted that the thicknesses of the first barrier layer and the second barrier layer may be individually controlled to customize the performance for a particular application.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

1. A semiconductor structure comprising:
a conductive layer over a substrate;
an etch buffer layer over the conductive layer;
a dielectric layer over the etch buffer layer;
a first trench and a first via through the dielectric layer, a first recess being formed in the conductive layer under the first via;
a second trench and a second via through the dielectric layer, the second trench being narrower than the first trench, a second recess being formed in the conductive layer under the second via, the second recess being deeper than the first recess;
a first barrier layer along sidewalls of the first trench, the first via, the second trench, and the second via, the first barrier layer being substantially removed along the bottom of the first via and the second via;
a second barrier layer along surfaces of the first trench, the first via, the second trench, and the second via, wherein a portion of material from the conductive layer is interposed between the first barrier layer and the second barrier layer; and
conductive plugs over the second barrier layer in the first trench, the first via, the second trench, and the second via;
wherein the first recess is greater than about 50 Å when a ratio of a width of the first trench along a surface of the dielectric layer to a width of the first via along a surface of the etch stop layer is less than about 10 and is less than about 50 Å when the ratio of the width of the first trench along the surface of the dielectric layer to the width of the first via along the surface of the etch stop layer is greater than about 10; and
wherein the first recess has a first dimension at the etch buffer layer and a second dimension at a bottom of the first recess, the second dimension being less than about 95% of the first dimension.

2. The semiconductor structure of claim 1, wherein the first via and the second via have a width less than or equal to about 0.15 μm.

3. The semiconductor structure of claim 1, wherein the first barrier layer has a thickness between about 5 Å and about 300 Å.

4. The semiconductor structure of claim 1, wherein the second barrier layer has a thickness between about 5 Å and about 300 Å.

5. A semiconductor structure comprising:
a conductive layer over a substrate;
a dielectric layer overlying the conductive layer;
a first trench and a first via through the dielectric layer;
a second trench and a second via through the dielectric layer, the second trench being narrower than the first trench;
a first barrier layer along sidewalls of the first trench, the first via, the second trench, and the second via, the first barrier layer being substantially removed along the bottom of the first via and the second via;
a first recess in the conductive layer along the bottom of the first via;
a second recess in the conductive layer along the bottom of the second via, the second recess being deeper than the first recess;
a second barrier layer along surfaces of the first trench, the first via, the second trench, and the second via; and
conductive plugs over the second barrier layer in the first trench, the first via, the second trench, and the second via.

6. The semiconductor structure of claim 5, wherein the first via and the second via have a width less than or equal to about 0.15 μm.

7. The semiconductor structure of claim 5, wherein the first barrier layer has a thickness between about 5 Å and about 300 Å.

8. The semiconductor structure of claim 5, wherein the second barrier layer has a thickness between about 5 Å and about 300 Å.

9. The semiconductor structure of claim 5, further comprising an etch stop layer between the dielectric layer and the conductive layer.

10. A semiconductor structure comprising:
a substrate with a first conductive layer formed thereon;
a dielectric layer overlying the conductive layer; and
a via formed in the dielectric layer and filled with a conductive material, the via having a bottom and sidewalls, a first barrier layer formed along the sidewalls of the via, a second barrier layer formed on the first barrier layer along the sidewalls of the via and on the conductive layer along the bottom of the via, and a metal layer interposed between a portion of the first barrier layer and the second barrier layer.

11. The semiconductor structure of claim 10, wherein the first conductive layer includes a recess having a depth about 1 Å to about 100 Å.

12. The semiconductor structure of claim 10, wherein a ratio of a thickness of the first barrier layer to a thickness of the second barrier layer along the sidewalls is between about 1:10 and about 10:1.

13. The semiconductor structure of claim 12, wherein the first barrier layer has a thickness between about 5 Å and about 300 Å.

14. The semiconductor structure of claim 12, wherein the second barrier layer has a thickness between about 5 Å and about 300 Å.

15. A semiconductor structure comprising:
a substrate having a conductive layer formed thereon;
an etch buffer layer over the conductive layer;
a dielectric layer overlying the etch buffer layer; and
an opening through the dielectric layer and the etch buffer layer, the opening being filled with a conductive material in electric contact with at least a portion of the conductive layer, the opening having a first dimension at the surface of the dielectric layer and a second dimension at the etch stop layer;
wherein the conductive layer has a recess under the opening, the recess being deeper than about 50 Å when the ratio of the first dimension to the second dimension is less than about 10 and being less than about 50 Å when the ratio of the first dimension to the second dimension is greater than about 10.

16. The semiconductor structure of claim 15, further comprising one or more barrier layers formed along sidewalls and bottom of the opening.

17. The semiconductor structure of claim 16, wherein the bottom of the opening has fewer barrier layers formed thereon than along the sidewalls.

18. A semiconductor structure comprising:
a substrate having a conductive layer formed thereon;
an etch buffer layer over the conductive layer;
a dielectric layer overlying the etch buffer layer;
an opening through the dielectric layer and the etch stop layer, the opening being filled with a conductive material in electric contact with at least a portion of the conductive layer; and
a recess in the conductive layer under the opening, the recess having a first dimension at the etch stop layer and a second dimension at a bottom of the recess, the second dimension being less than about 95% of the first dimension.

19. The semiconductor structure of claim 18, further comprising one or more barrier layers formed along sidewalls and bottom of the opening.

20. The semiconductor structure of claim 19, wherein the bottom of the opening has fewer barrier layers formed thereon than along the sidewalls.
